(19) United States
(12) Patent Application Publication
(10) Pub. No.: US 2010/0167213 A1
(43) Pub. Date: Jul. 1, 2010

(54) SEMICONDUCTOR DEVICE MANUFACTURING METHOD

(76) Inventors: Yuriko SEINO, Kanagawa-ken (JP); Tatsuhiko EMA, Oita-ken (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/621,146

(22) Filed: Nov. 18, 2009

(30) Foreign Application Priority Data
Dec. 26, 2008 (JP) 2008-334778

(51) Int. Cl. G03F 7/20

(52) U.S. Cl. 430/319

(57) ABSTRACT

A semiconductor device manufacturing method includes: forming a first anti-reflective coating on a semiconductor wafer; forming a second anti-reflective coating on the first anti-reflective coating; forming a resist film on the second anti-reflective coating; selectively exposing the resist film to light; developing the resist film and the anti-reflective coatings after the light exposure; and processing the semiconductor wafer using as a mask a pattern of the resist film obtained by the development. The photosensitizer concentration of the first anti-reflective coating is higher than the photosensitizer concentration of the second anti-reflective coating.

### CROSS-REFERENCE TO RELATED APPLICATIONS

This application is based upon and claims the benefit of priority from the prior Japanese Patent Application No. 2008-334778, filed on Dec. 26, 2008; the entire contents of which are incorporated herein by reference.

### BACKGROUND OF THE INVENTION

1. Field of the Invention

This invention relates to a semiconductor device manufacturing method.

2. Background Art

The ion implantation process, for instance, in semiconductor device manufacturing is a process for using a resist pattern as a mask to introduce impurities into a semiconductor wafer. In this process, to avoid damaging the wafer surface, it is desirable not to use dry etching in forming a resist pattern. Thus, International Publication WO 2006/059452 Pamphlet, for instance, discloses use of a resist lower layer made of an anti-reflective coating, which can be dissolved in a resist developer and developed away together with the resist.

Conventionally, in a resist patterning process based on a developer-soluble anti-reflective coating, non-photosensitive anti-reflective coatings are predominantly used, because they have little chemical interaction with the resist, and hence have the advantage of being usable substantially independent of resists. However, the non-photosensitive anti-reflective coating has a problem of corrosion from the lateral side also in the non-light-exposed portion (the portion below the resist film remaining after development), which makes it difficult to control the shape of the anti-reflective coating.

### SUMMARY OF THE INVENTION

According to an aspect of the invention, there is provided a semiconductor device manufacturing method including: forming an anti-reflective coating on a semiconductor wafer, the anti-reflective coating having varied photosensitizer concentration along its thickness; forming a resist film on the anti-reflective coating; selectively exposing the resist film to light; developing the resist film and the anti-reflective coating after the light exposure; and processing the semiconductor wafer using as a mask a pattern of the resist film obtained by the development.

### BRIEF DESCRIPTION OF THE DRAWINGS

FIGS. 1A to 1C are schematic views showing a semiconductor device manufacturing method according to a first embodiment of the invention;

FIGS. 2A and 2B are schematic views showing the processes continuing from FIG. 1C;

FIGS. 3A and 3B are schematic views showing a semiconductor device manufacturing method according to a second embodiment of the invention;

FIGS. 4A and 4B are schematic views showing the processes continuing from FIG. 3B;

FIG. 5 is a schematic view showing a concentration distribution of a photoacid generator along the thickness of an anti-reflective coating according to the second embodiment;

FIGS. 6A and 6B are schematic views showing a semiconductor device manufacturing method according to a third embodiment of the invention;

FIGS. 7A and 7B are schematic views showing the processes continuing from FIG. 6B;

FIGS. 8A and 8B are schematic views showing a semiconductor device manufacturing method according to a comparative example;

FIGS. 9A to 9C are schematic views showing a semiconductor device manufacturing method according to a fourth embodiment of the invention;

FIGS. 10A and 10B are schematic views showing the processes continuing from FIG. 9C;

FIGS. 11A and 11B are schematic views showing a semiconductor device manufacturing method according to a fifth embodiment of the invention;

FIGS. 12A and 12B are schematic views showing the processes continuing from FIG. 11B;

FIGS. 13A and 13B are schematic views showing a semiconductor device manufacturing method according to a sixth embodiment of the invention;

FIGS. 14A and 14B are schematic views showing the processes continuing from FIG. 13B;

FIGS. 15A and 15B are schematic views showing a stepped portion on a substrate; and

FIGS. 16A and 16B are schematic views showing residues of an anti-reflective coating in the stepped portion on the substrate.

### DETAILED DESCRIPTION OF THE INVENTION

### First Embodiment

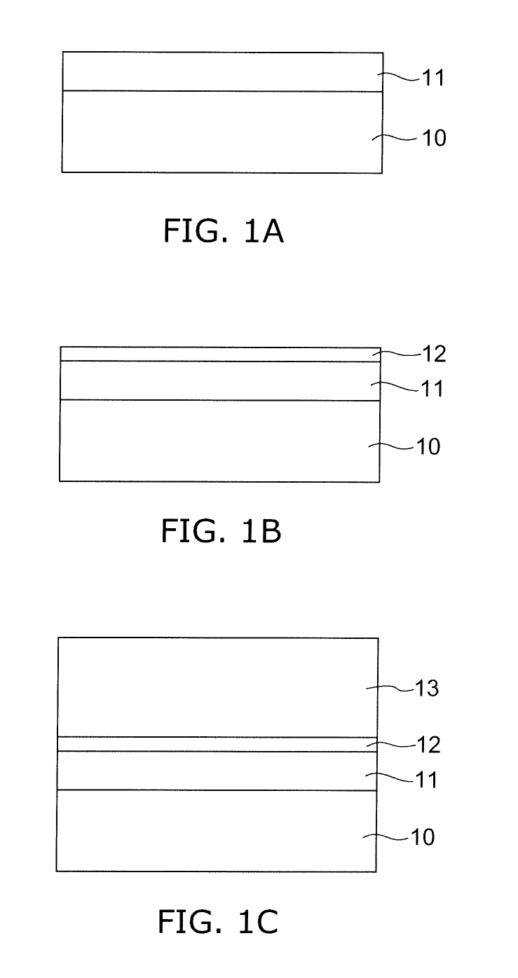

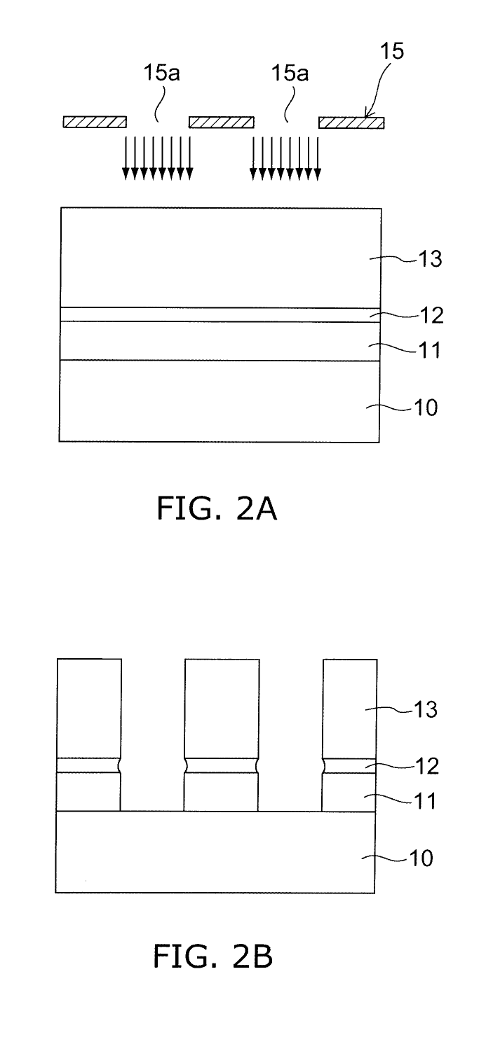

FIGS. 1A to 2B show a semiconductor device manufacturing method according to a first embodiment of the invention.

First, as shown in FIG. 1A, a first anti-reflective coating 11 is formed on a semiconductor wafer 10. The semiconductor wafer 10 has a configuration in which an oxide film, a nitride film, and a film to be processed, such as a metal film, are formed on a substrate (such as a silicon substrate). Alternatively, the semiconductor wafer may consist only of a substrate. The semiconductor wafer 10 is fixed on a rotary support by a vacuum chuck. The first anti-reflective coating 11 is formed by the spin-coating method of dropping the first anti-reflective coating 11 in liquid form on the semiconductor wafer 10 and spinning the semiconductor wafer 10. After dropping and applying the first anti-reflective coating 11, baking treatment is performed to evaporate solvent and cure the first anti-reflective coating 11.

Next, again by the spin-coating method, as shown in FIG. 1B, a second anti-reflective coating 12 is formed on the first anti-reflective coating 11. After dropping and applying the second anti-reflective coating 12, baking treatment is performed to evaporate solvent and cure the second anti-reflective coating 12.

The first anti-reflective coating 11 and the second anti-reflective coating 12 are both soluble in a developer for resist development described later. However, in the first anti-reflective coating 11, only the light-exposed portion dissolves in the developer, but the non-light-exposed portion does not dissolve in the developer. That is, without light exposure, the first anti-reflective coating 11 is originally insoluble in the developer. Specifically, the first anti-reflective coating 11 is photosensitive to exposure light during resist exposure and contains, as a photosensitizer, a photoacid generator (PAG), which generates acid upon light exposure. The first anti-reflective coating 11 is illustratively of the positive type, and a portion where acid is generated by irradiation with exposure light becomes soluble in the developer by the action of the acid.

The second anti-reflective coating 12 contains substantially no photosensitizer (photoacid generator), and both the light-exposed portion and the non-light-exposed portion dissolve in the resist developer. In regard to the overall anti-reflective coating with the first anti-reflective coating 11 and the second anti-reflective coating 12 stacked therein, the lower portion including a portion in contact with the semiconductor wafer 10 has a higher photoacid generator concentration than the upper portion including a portion in contact with a resist film to be formed in a later process.

Next, as shown in FIG. 1C, a resist film 13 is formed to a thickness of e.g. 200 nm on the second anti-reflective coating 12. This resist film 13 is a chemically amplified positive resist in which the light-exposed portion generates acid and becomes soluble in the developer.

Next, as shown in FIG. 2A, using a reticle 15 in which light transmitting portions 15a are selectively formed in accordance with a desired circuit pattern, the resist film 13 is selectively irradiated with exposure light. This exposure light can be suitably selected from among g-line, i-line, KrF excimer laser light, ArF excimer laser light, electron beam, EUV (extreme ultraviolet) light, X-ray and the like in accordance with the type of the resist film 13.

After this light exposure, as shown in FIG. 2B, the resist film 13 is selectively removed and patterned by development illustratively using an alkaline developer. That is, a portion of the resist film 13 where acid is generated by irradiation with exposure light becomes soluble in the developer and is removed.

The second anti-reflective coating 12 is non-photosensitive, containing substantially no photosensitizer, and both the light-exposed portion and the non-light-exposed portion are soluble in the developer. Hence, the second anti-reflective coating 12 is corroded on the lateral side also in the non-light-exposed portion (a portion below the resist film 13 in FIG. 2B). On the other hand, in the first anti-reflective coating 11, only the light-exposed portion is soluble in the aforementioned developer, and is removed. In a portion where the resist film 13 is removed (the light-exposed portion), both the second anti-reflective coating 12 and the first anti-reflective coating 11 are removed by the developer, and the surface of the semiconductor wafer 10 is exposed to the space from which they are removed.

After the aforementioned development, the pattern of the resist film 13 is used as a mask to perform various processes, such as ion implantation, wet processing, and dry etching, on the semiconductor wafer 10.

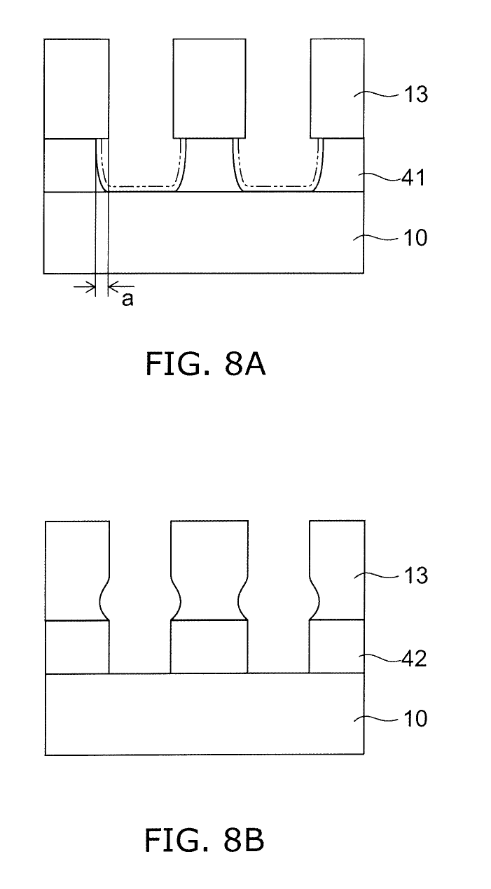

Conventionally, in a resist patterning process based on a developer-soluble anti-reflective coating, non-photosensitive anti-reflective coatings are predominantly used. This is because a non-photosensitive anti-reflective coating has little chemical interaction with the resist, and hence is usable substantially independent of the type of the resist and readily compatible with the resist. However, in the non-photosensitive anti-reflective coating, the light-exposed portion and the non-light-exposed portion are both developed. Hence, as shown in FIG. 8A, it has a problem of being difficult in controlling the shape of the anti-reflective coating 41 below the resist film 13 left on the wafer.

FIG. 8A schematically shows a non-photosensitive developer-soluble anti-reflective coating 41 formed as a single layer between a semiconductor wafer 10 and a resist film 13, where the resist film 13 has been subjected to selective light exposure and development. The non-photosensitive anti-reflective coating 41 is isotropically etched by a developer, and a portion below the resist film 13 left on the wafer (the non-light-exposed portion) is also corroded and thinned from the lateral side (as indicated by the solid line), which may make difficult to stably support the resist film 13 and cause a collapse of the resist film 13.

Here, if the etching time is set shorter to reduce corrosion on the lateral side of the anti-reflective coating 41, there is concern that a part of the anti-reflective coating 41 is left as residues on the surface of the semiconductor wafer 10 as shown by the double dot-dashed line in FIG. 8A.

On the other hand, if a photosensitive (photoacid generator-containing) anti-reflective coating is used so that the light-exposed portion and the non-light-exposed portion exhibit etching selectivity in the developer (this case is shown in FIG. 8B), interaction between the anti-reflective coating 42 and the resist film 13, both photosensitive, is enhanced due to, for instance, difference in the level of light exposure therebetween. This causes a problem of being difficult in controlling the shape of the pattern of the resist film 13. To prevent this problem, a resist film 13 having little interaction with the anti-reflective coating 42 needs to be used. This restricts available types of resist films, and may cause yield decrease and cost increase depending on the type of the resist film used.

In contrast, in this embodiment, the second anti-reflective coating 12 in direct contact with the resist film 13 is non-photosensitive and has little interaction with the resist film 13. This prevents shape degradation of the resist film 13 after development. Furthermore, the first anti-reflective coating 11 in contact with the semiconductor wafer 10 is photosensitive. Thus, the non-light-exposed portion of the first anti-reflective coating 11 is insoluble in the developer, which prevents shape degradation of the first anti-reflective coating 11 below the resist film 13 left after development. Hence, this embodiment is superior in shape controllability and dimension controllability of the resist film and the anti-reflective coating in resist patterning based on the anti-reflective coating. Thus, the resist pattern obtained by the process of this embodiment can be used as a mask to perform ion implantation, wet etching, dry etching and the like with high accuracy.

The second anti-reflective coating 12 serves to reduce interaction with the resist film 13. Hence, the resist film 13 formed on the second anti-reflective coating 12 is not substantially restricted in its type. On the other hand, the first anti-reflective coating 11 is photosensitive. Hence, if the resist film 13 is directly formed thereon, it is difficult to achieve compatibility with the resist film 13, which is also photosensitive. However, in this embodiment, the first anti-reflective coating 11 is not in direct contact with the resist film 13. Hence, there is no interaction therebetween, and the types of the first anti-reflective coating 11 and the resist film 13 can be freely selected without consideration for compatibility with each other.

Because the second anti-reflective coating 12 is non-photosensitive, corrosion from the lateral side occurs also in the non-light-exposed portion. Hence, the function of supporting the resist film 13 by being left therebelow is preferably served by the first anti-reflective coating 11, whose non-light-exposed portion is insoluble in the developer, and the thickness of the second anti-reflective coating 12 is preferably as thin as possible. However, if it is an ultrathin film of approximately several nm, defects such as pinholes are likely to occur. Hence, in this embodiment, the second anti-reflective coating 12 is formed to a thickness of e.g. approximately 10 nm.

On the other hand, the first anti-reflective coating 11, which is superior in shape controllability at the time of development as described above, serves to stably support the resist film 13. Hence, it is made thicker than the second anti-reflective coating 12 and is formed to a thickness of approximately several tens nm (such as 30 nm) in this embodiment.

Furthermore, in the first anti-reflective coating 11, which is photosensitive, by suitably setting the photosensitizer concentration therein, the light-exposed portion can be removed throughout the thickness even in a relatively short etching time. Reduced etching time serves to limit the amount of corrosion on the lateral side of the second anti-reflective coating 12.

Furthermore, in this embodiment, the heterogeneous two-layer structure of anti-reflective coatings serves to adjust optical constants (such as refractive index and extinction coefficient) for each layer and has a higher degree of freedom of combinations of the film thickness, refractive index, extinction coefficient and the like determining the anti-reflection performance than a single-layer anti-reflective coating. Depending on the combination, it is also possible to dramatically increase the anti-reflection effect, and significantly improve the dimension controllability of the resist pattern.

According to experiments by the inventors, in the above comparative example shown in FIG. 8A where the anti-reflective coating is entirely a non-photosensitive anti-reflective coating 41, the amount of corrosion, a, on the lateral side of the anti-reflective coating 41 was 30 nm. In contrast, in this embodiment, the thickness of the non-photosensitive second anti-reflective coating 12 is as thin as approximately ¼ of the thickness of the overall anti-reflective coating composed of the anti-reflective coating 11 and the anti-reflective coating 12. Hence, the amount of corrosion on the lateral side of the anti-reflective coating 12 in the situation of FIG. 2B was reduced to 5 nm.

Furthermore, because of the aforementioned higher degree of freedom of combinations of various parameters determining the anti-reflection performance, the combination can be suitably set to dramatically improve the anti-reflection performance during light exposure. Thus, the width of dimensional variation (3σ) in the resist pattern throughout the wafer was 15 nm in the above comparative example, but reduced to 7 nm in this embodiment. Here, 3σ gives a measure of dimensional variation. In the above comparative example, 99.7% of all values fall within the average ±15 nm, whereas in this embodiment, 99.7% of all values fall within the average ±7 nm.

### Second Embodiment

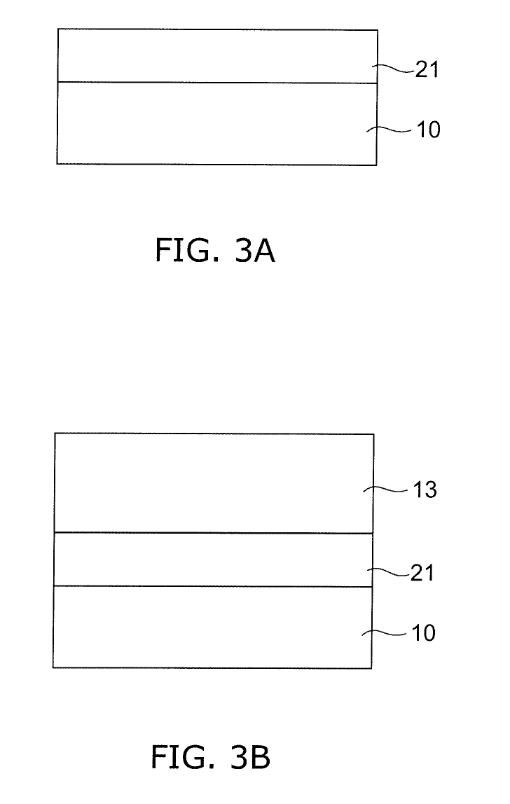

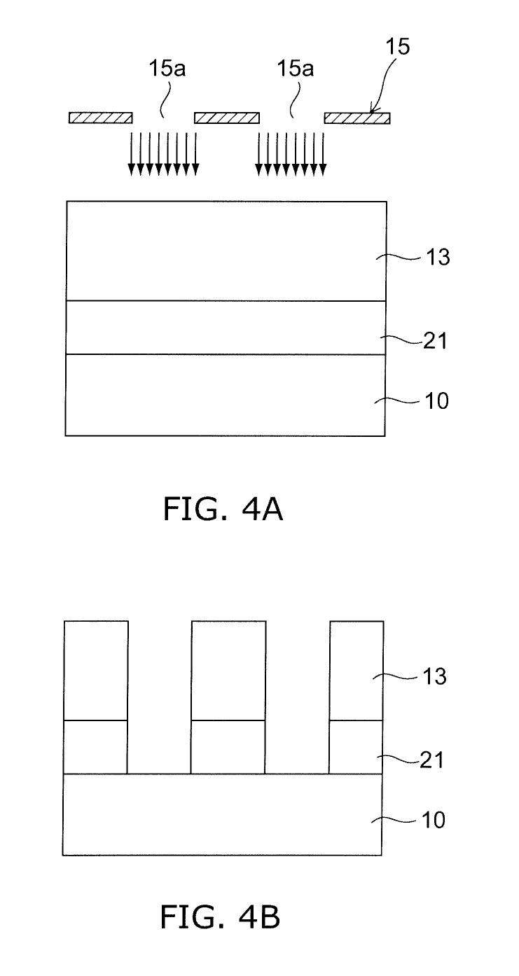

Next, FIGS. 3A to 4B show a semiconductor device manufacturing method according to a second embodiment of the invention.

First, as shown in FIG. 3A, an anti-reflective coating 21 is formed on a semiconductor wafer 10. Specifically, the anti-reflective coating 21 is formed by the spin-coating method of dropping the anti-reflective coating 21 in liquid form on the semiconductor wafer 10 fixed on a rotary support by a vacuum chuck and spinning the semiconductor wafer 10. After dropping and applying the anti-reflective coating 21, baking treatment is performed to evaporate solvent and cure the anti-reflective coating 21. The thickness of the anti-reflective coating 21 is e.g. approximately 40 nm.

The anti-reflective coating 21 is photosensitive to exposure light during resist exposure and contains, as a photosensitizer, a photoacid generator, which generates acid upon light exposure. A portion of the anti-reflective coating 21 where acid is generated upon light exposure becomes soluble in a developer.

In this embodiment, when the anti-reflective coating 21 is formed on the semiconductor wafer 10, a concentration gradient of the photoacid generator is produced along the film thickness. Specifically, by adjusting the molecular weight of the photoacid generator, the number of rotations of the semiconductor wafer 10 during the aforementioned spin-coating, baking temperature, baking time, and the atmosphere pressure on the semiconductor wafer 10, for instance, the photoacid generator is moved along the film thickness to produce a concentration gradient of the photoacid generator along the film thickness.

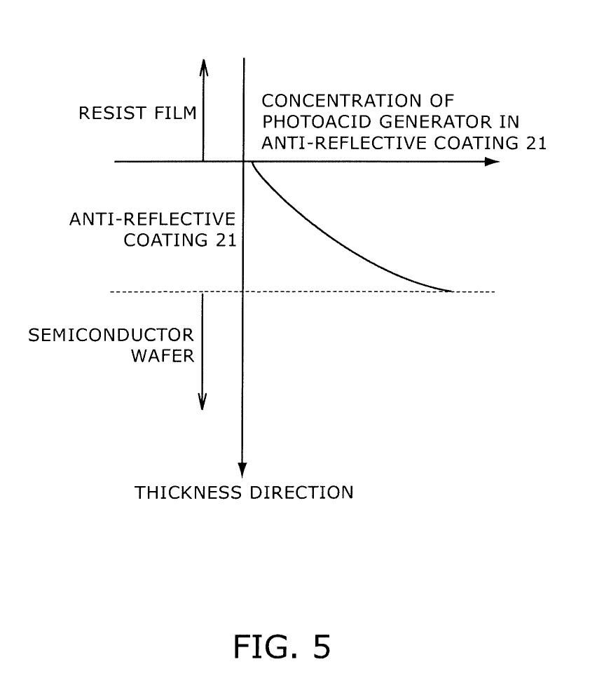

FIG. 5 illustrates a concentration distribution of the photoacid generator along the thickness of the anti-reflective coating 21.

In the anti-reflective coating 21, the photoacid generator concentration increases from the upper portion including a portion in contact with the resist film toward the lower portion including a portion in contact with the semiconductor wafer 10. Here, the concentration variation of the photoacid generator from the upper portion toward the lower portion does not need to be continuous, but may be stepwise. In sum, in the anti-reflective coating 21, the concentration of the photoacid generator only needs to be higher in the portion in contact with the semiconductor wafer 10 than in the portion in contact with the resist film.

After the anti-reflective coating 21 is formed, as shown in FIG. 3B, a resist film 13 is formed to a thickness of e.g. 200 nm on the anti-reflective coating 21. This resist film 13 is a chemically amplified positive resist in which the light-exposed portion generates acid and becomes soluble in the developer.

Next, as shown in FIG. 4A, using a reticle 15 in which light transmitting portions 15a are selectively formed in accordance with a desired circuit pattern, the resist film 13 is selectively irradiated with exposure light.

After this exposure, as shown in FIG. 4B, the resist film is selectively removed and patterned by development illustratively using an alkaline developer. That is, a portion of the resist film 13 where acid is generated by irradiation with exposure light becomes soluble in the developer and is removed.

In the anti-reflective coating 21 containing the photosensitizer (photoacid generator), only the light-exposed portion is soluble in the aforementioned developer, and is removed. In the light-exposed portion, the anti-reflective coating 21 is removed by the developer throughout the thickness, and the surface of the semiconductor wafer 10 is exposed to the space from which it is removed.

After the aforementioned development, the pattern of the resist film 13 is used as a mask to perform various processes, such as ion implantation, wet processing, and dry etching, on the semiconductor wafer 10.

The anti-reflective coating 21 is photosensitive, and the light-exposed portion and the non-light-exposed portion exhibit etching selectivity in the developer. This prevents shape degradation due to corrosion on the lateral side of the non-light-exposed portion. Furthermore, by relatively decreasing the photoacid generator concentration in a portion of the anti-reflective coating 21 in direct contact with the resist film 13, it is possible to reduce interaction with the resist film 13 and prevent shape degradation of the resist film 13 after development. Furthermore, the resist film 13 formed on the anti-reflective coating 21 is not substantially restricted in its type.

Hence, like the above first embodiment, this embodiment is also superior in shape controllability and dimension controllability of the resist film and the anti-reflective coating in resist patterning based on the anti-reflective coating. Thus, the resist pattern obtained by the process of this embodiment can be used as a mask to perform ion implantation, wet etching, dry etching and the like with high accuracy.

Furthermore, in this embodiment, because the anti-reflective coating 21 is a single homogeneous layer, there is no need to perform forming the anti-reflective coating multiple times, but the coating process can be completed at one time. This serves to prevent increase in the number of processes and reduce cost.

### Third Embodiment

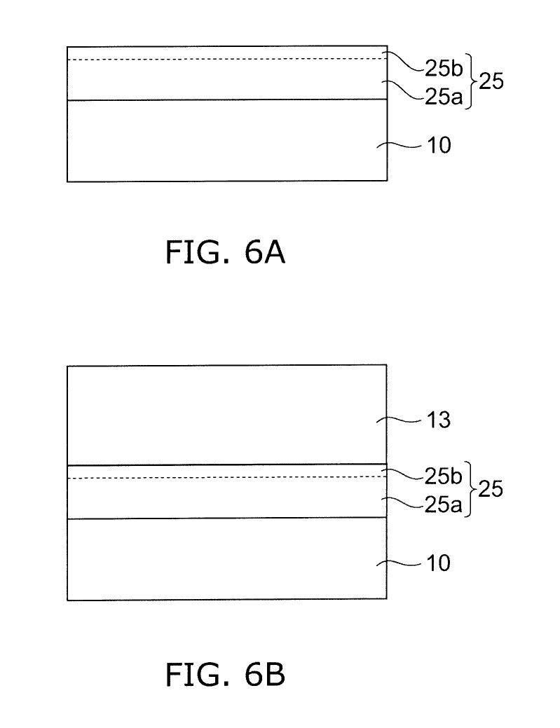

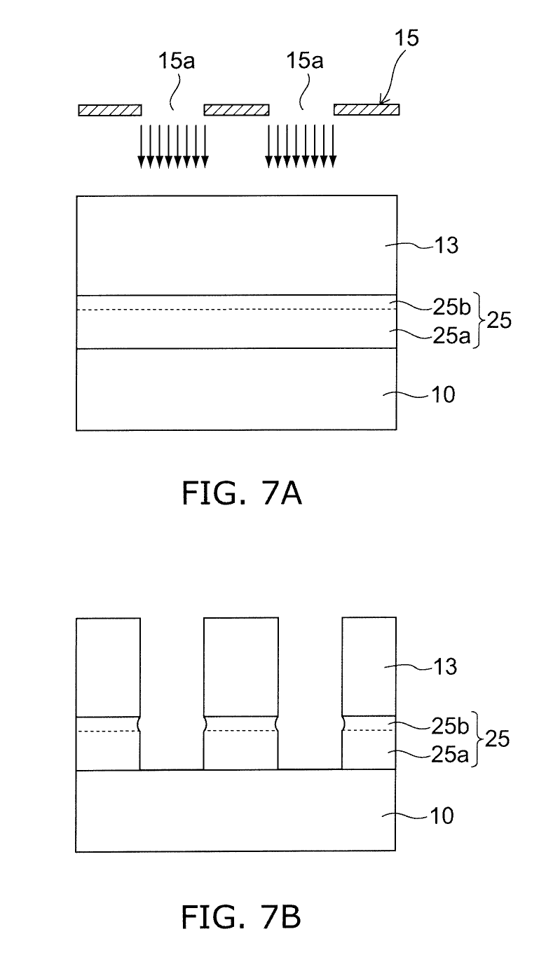

Next, FIGS. 6A to 7B show a semiconductor device manufacturing method according to a third embodiment of the invention.

First, as shown in FIG. 6A, an anti-reflective coating 25 is formed on a semiconductor wafer 10. Specifically, the anti-reflective coating 25 is formed by the spin-coating method of dropping the anti-reflective coating 25 in liquid form on the semiconductor wafer 10 fixed on a rotary support by a vacuum chuck and spinning the semiconductor wafer 10. After dropping and applying the anti-reflective coating 25, baking treatment is performed to evaporate solvent and cure the anti-reflective coating 25. The thickness of the anti-reflective coating 25 is e.g. approximately 40 nm.

In this embodiment, when the anti-reflective coating 25 is formed on the semiconductor wafer 10, a concentration variation of the photoacid generator is produced along the film thickness. Specifically, a solution in which two types of polymers, photosensitive and non-photosensitive, are mixed is dropped on the semiconductor wafer 10, and a concentration variation of the polymers is produced along the film thickness using, for instance, the interaction between the semiconductor wafer 10 and the polymers, the polymer surface energy, the interaction between the polymers, and hydrophobicity to the surface of the semiconductor wafer 10.

Specifically, the lower portion on the semiconductor wafer 10 side is caused to contain the photosensitive polymer in a relatively large proportion, and the upper portion is caused to contain the non-photosensitive polymer in a relatively large proportion. That is, in the anti-reflective coating 25, the lower portion 25a including a portion in contact with the semiconductor wafer 10 has a relatively high concentration of the photosensitive polymer and is substantially photosensitive, whereas the upper portion 25b thereabove has a relatively high concentration of the non-photosensitive polymer and is substantially non-photosensitive.

After the anti-reflective coating 25 is formed, as shown in FIG. 6B, a resist film 13 is formed to a thickness of e.g. 200 nm on the anti-reflective coating 25. This resist film 13 is a chemically amplified positive resist in which the light-exposed portion generates acid and becomes soluble in the developer.

Next, as shown in FIG. 7A, using a reticle 15 in which light transmitting portions 15a are selectively formed in accordance with a desired circuit pattern, the resist film 13 is selectively irradiated with exposure light. After this exposure, as shown in FIG. 7B, the resist film 13 is selectively removed and patterned by development illustratively using an alkaline developer. That is, a portion of the resist film 13 where acid is generated by irradiation with exposure light becomes soluble in the developer and is removed.

The upper portion 25b of the anti-reflective coating 25 is substantially non-photosensitive, and both the light-exposed portion and the non-light-exposed portion are dissolved in the developer. On the other hand, in the lower portion 25a of the anti-reflective coating 25, only the light-exposed portion is dissolved in the aforementioned developer, and is removed.

After the aforementioned development, the pattern of the resist film 13 is used as a mask to perform various processes, such as ion implantation, wet processing, and dry etching, on the semiconductor wafer 10.

In this embodiment, the upper portion 25b of the anti-reflective coating 25 in direct contact with the resist film 13 is non-photosensitive and has little interaction with the resist film 13. This prevents shape degradation of the resist film 13 after development. Furthermore, the lower portion 25a in contact with the semiconductor wafer 10 is photosensitive. Thus, the non-light-exposed portion of the upper portion 25a is insoluble in the developer, which prevents shape degradation of a portion below the resist film 13 left after development. Hence, this embodiment is also superior in shape controllability and dimension controllability of the resist film and the anti-reflective coating in resist patterning based on the anti-reflective coating. Thus, the resist pattern obtained by the process of this embodiment can be used as a mask to perform ion implantation, wet etching, dry etching and the like with high accuracy.

The non-photosensitive upper portion 25b serves to reduce interaction with the resist film 13. Hence, the resist film 13 formed thereon is not substantially restricted in its type. On the other hand, the lower portion 25a is photosensitive. Hence, if the resist film 13 is directly formed thereon, it is difficult to achieve compatibility with the resist film 13, which is also photosensitive. However, in this embodiment, the lower portion 25a is not in direct contact with the resist film 13. Hence, there is no interaction therebetween, and the type of the resist film 13 can be selected with a high degree of freedom.

Furthermore, in the upper portion 25b where the non-light-exposed portion is also soluble in the developer, corrosion from the lateral side occurs also in a portion below the resist film 13. Hence, the function of supporting the resist film 13 by being left therebelow is preferably served by the lower portion 25a, whose non-light-exposed portion is insoluble in the developer. More specifically, the lower portion 25a, which is superior in shape controllability at the time of development, serves to stably support the resist film 13. Hence, components in the aforementioned liquid mixture, the component ratio thereof, and the condition during spin-coating, for instance, are preferably adjusted so that the lower portion 25a is thicker than the upper portion 25b.

Furthermore, in the lower portion 25a, which is photosensitive, by suitably setting the photosensitizer concentration therein, the light-exposed portion can be removed throughout the thickness even in a relatively short etching time. Reduced etching time serves to limit the amount of corrosion on the lateral side of the upper portion 25b.

Furthermore, in this embodiment, there is no need to perform forming the anti-reflective coating 25 multiple times, but the coating process can be completed at one time. This serves to prevent increase in the number of processes and reduce cost.

### Fourth Embodiment

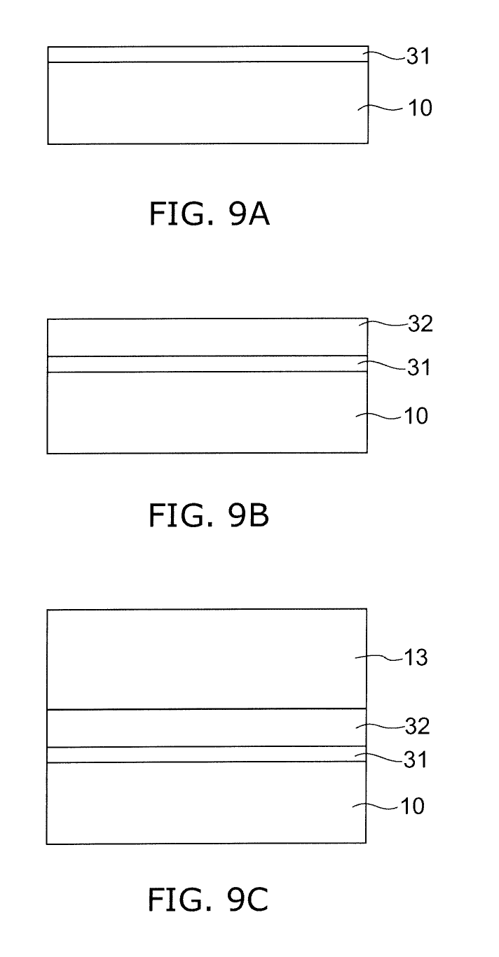

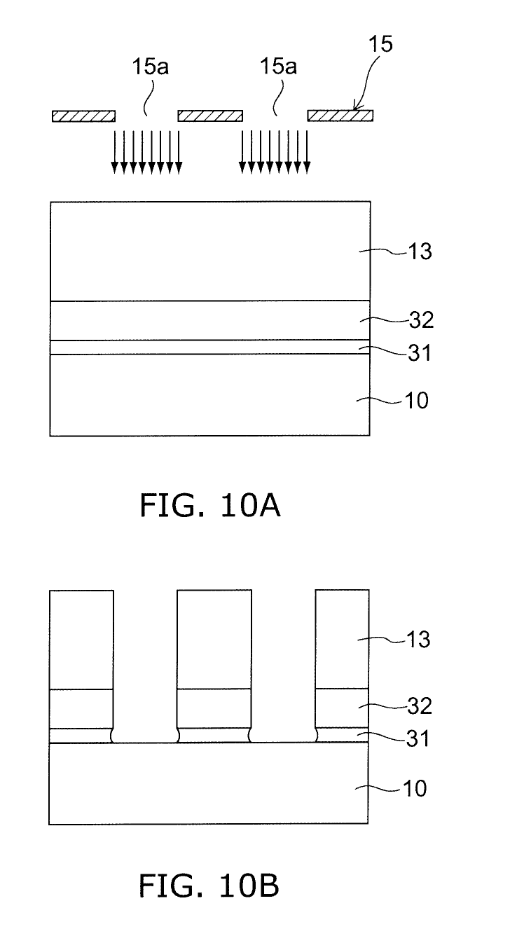

Next, FIGS. 9A to 10B show a semiconductor device manufacturing method according to a fourth embodiment of the invention.

First, as shown in FIG. 9A, a first anti-reflective coating 31 is formed on a semiconductor wafer 10. Specifically, the first anti-reflective coating 31 is formed by the spin-coating method of dropping the first anti-reflective coating 31 in liquid form on the semiconductor wafer 10 fixed on a rotary support by a vacuum chuck and spinning the semiconductor wafer 10. After dropping and applying the first anti-reflective coating 31, baking treatment is performed to evaporate solvent and cure the first anti-reflective coating 31.

Next, again by the spin-coating method, as shown in FIG. 9B, a second anti-reflective coating 32 is formed on the first anti-reflective coating 31. After dropping and applying the second anti-reflective coating 32, baking treatment is performed to evaporate solvent and cure the second anti-reflective coating 32.

The first anti-reflective coating 31 contains substantially no photosensitizer (photoacid generator), and both the light-exposed portion and the non-light-exposed portion dissolve in the resist developer. The second anti-reflective coating 32 is photosensitive to exposure light during resist exposure and contains, as a photosensitizer, a photoacid generator, which generates acid upon light exposure. The second anti-reflective coating 32 is illustratively of the positive type, and a portion where acid is generated by irradiation with exposure light becomes soluble in the developer.

In regard to the overall anti-reflective coating with the first anti-reflective coating 31 and the second anti-reflective coating 32 stacked therein, the lower portion including a portion in contact with the semiconductor wafer 10 has a lower photoacid generator concentration than the upper portion including a portion in contact with a resist film.

Next, as shown in FIG. 9C, a resist film 13 is formed to a thickness of e.g. 200 nm on the second anti-reflective coating 12. This resist film 13 is a chemically amplified positive resist in which the light-exposed portion generates acid and becomes soluble in the developer.

Next, as shown in FIG. 10A, using a reticle 15 in which light transmitting portions 15a are selectively formed in accordance with a desired circuit pattern, the resist film 13 is selectively irradiated with light. After this light exposure, as shown in FIG. 10B, the resist film 13 is selectively removed and patterned by development illustratively using an alkaline developer. That is, a portion of the resist film 13 where acid is generated by irradiation with exposure light becomes soluble in the developer and is removed.

After the aforementioned development, the pattern of the resist film 13 is used as a mask to perform various processes, such as ion implantation, wet processing, and dry etching, on the semiconductor wafer 10.

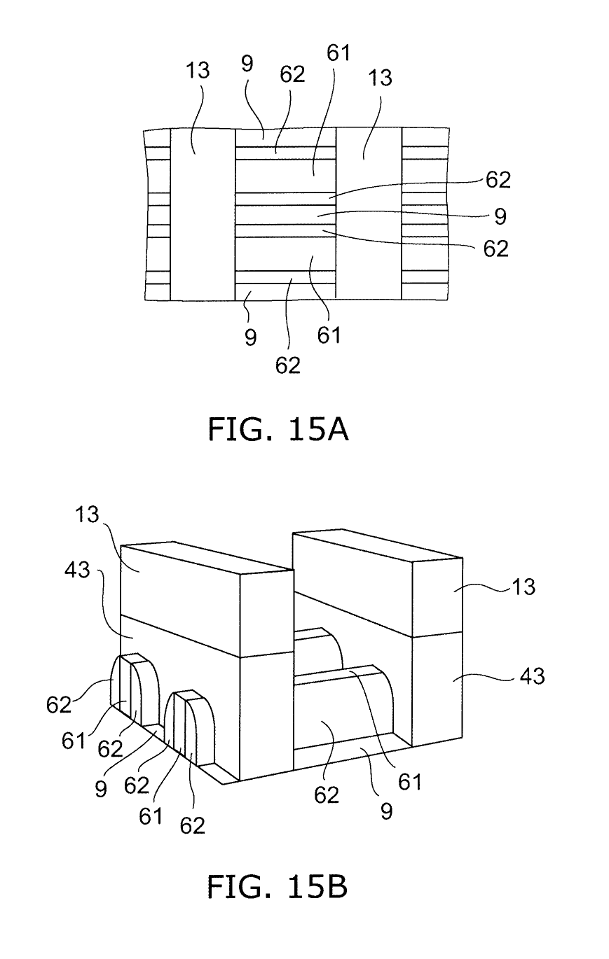

This embodiment is suitable to processing a stepped portion of the semiconductor wafer surface. An example of the stepped portion is shown in FIGS. 15A and 15B. FIGS. 15A and 15B show a neighborhood of the gate of a MOSFET (metal-oxide-semiconductor field effect transistor), in which FIG. 15B is a perspective view thereof, and FIG. 15A is a plan view thereof.

A gate electrode 61 is provided on a substrate 9, and a sidewall dielectric film 62 is provided on its sidewall. A resist film 13 is used as a mask for ion implantation for forming a source/drain region in the surface portion of the substrate 9.

More specifically, after an anti-reflective coating 43 and a resist film 13 are formed entirely on the substrate 9 so as to cover the gate electrode 61 and the sidewall dielectric film 62, selective light exposure and development are performed to expose only the region to be subjected to ion implantation. Thereby, the resist film 13 and the anti-reflective coating 43 on the surface of the substrate 9 between the sidewall dielectric films 62 of the adjacent gate electrodes 61 are removed.

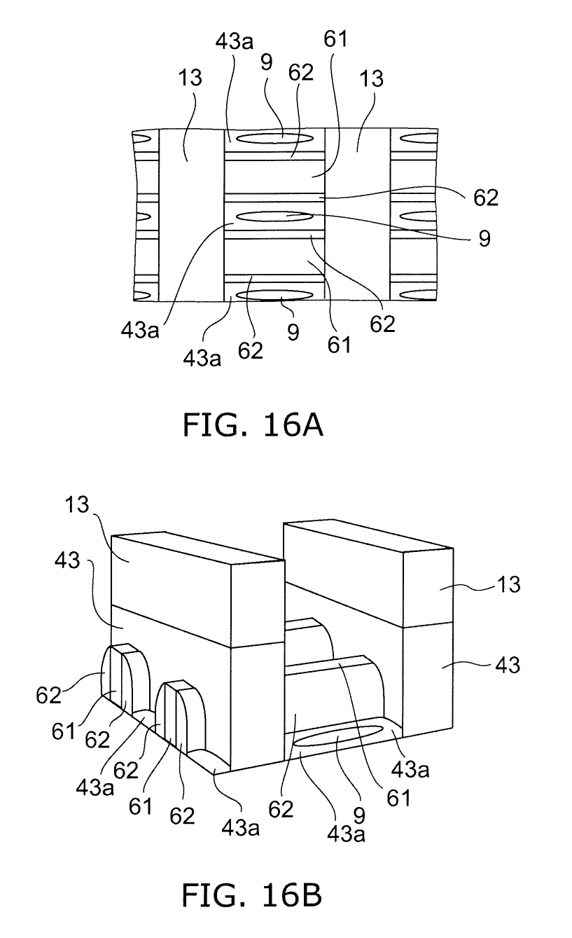

The light-exposed portion during this selective light exposure (that is, a portion where the surface of the substrate 9 is to be exposed by removing the anti-reflective coating 43 and the resist film 13) is located between the sidewall dielectric films 62 of the adjacent gate electrodes 61. However, if this gap is particularly deep and narrow, light may fail to reach deeply into the substrate 9 side. Here, if the anti-reflective coating 43 is photosensitive, there is concern that a part of the anti-reflective coating 43, which is the lower portion of the light-exposed portion on the substrate 9 side, fails to be exposed to light and is left as residues 43a even after development as shown in FIGS. 16A and 16B. In this case, the surface of the substrate 9 to be subjected to ion implantation might not be exposed or only a part is exposed.

In contrast, in this embodiment described above with reference to FIGS. 9A to 10B, the first anti-reflective coating 31, which is non-photosensitive and soluble in the developer even in the non-light-exposed portion, is formed on the semiconductor wafer 10 side where exposure light is more likely to fail to reach. Hence, even if such a stepped portion as illustrated in FIGS. 15A and 15B is present on the surface of the semiconductor wafer 10 and prevents light from reaching deeply into the gap, the first anti-reflective coating 31 formed on the semiconductor wafer 10 side can be dissolved in the developer and be removed. That is, as long as exposure light reaches the photosensitive second anti-reflective coating 32 thereon, the resist film 13, the second anti-reflective coating 32, and the first anti-reflective coating 31 in the light-exposed portion can be removed, and the surface of the semiconductor wafer 10 in that portion can be exposed. In this view, the thickness ratio between the first anti-reflective coating 31 and the second anti-reflective coating 32 is preferably set so as to ensure that the second anti-reflective coating 32 in the gap between the stepped portions is exposed to light throughout the thickness.

Because the first anti-reflective coating 31 is non-photosensitive, corrosion from the lateral side occurs also in the non-light-exposed portion. Hence, the function of supporting the resist film 13 by being left therebelow is preferably served by the second anti-reflective coating 32, whose non-light-exposed portion is insoluble in the developer. Thus, the second anti-reflective coating 32 is preferably made thicker than the first anti-reflective coating 31. For instance, in this embodiment, the thickness of the first anti-reflective coating 31 is approximately 10 nm, and the thickness of the second anti-reflective coating 32 is approximately several tens nm (such as 30 nm).

Furthermore, in the second anti-reflective coating 32, which is photosensitive, by suitably setting the photosensitizer concentration therein, the light-exposed portion can be removed throughout the thickness even in a relatively short etching time. Reduced etching time serves to limit the amount of corrosion on the lateral side of the first anti-reflective coating 31.

Furthermore, also in this embodiment, like the above first embodiment, the heterogeneous two-layer structure of anti-reflective coatings serves to adjust optical constants (such as refractive index and extinction coefficient) for each layer and has a higher degree of freedom of combinations of the film thickness, refractive index, extinction coefficient and the like determining the anti-reflection performance than a single-layer anti-reflective coating. Depending on the combination, it is also possible to dramatically increase the anti-reflection effect, and significantly improve the dimension controllability of the resist pattern.

### Fifth Embodiment

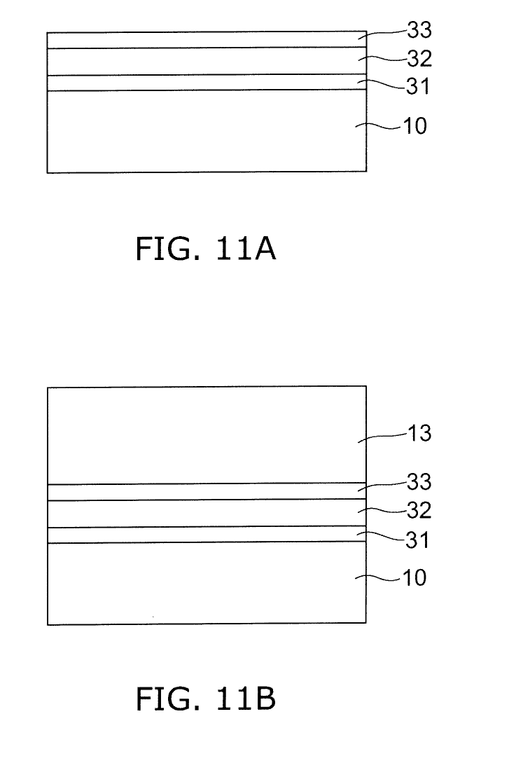

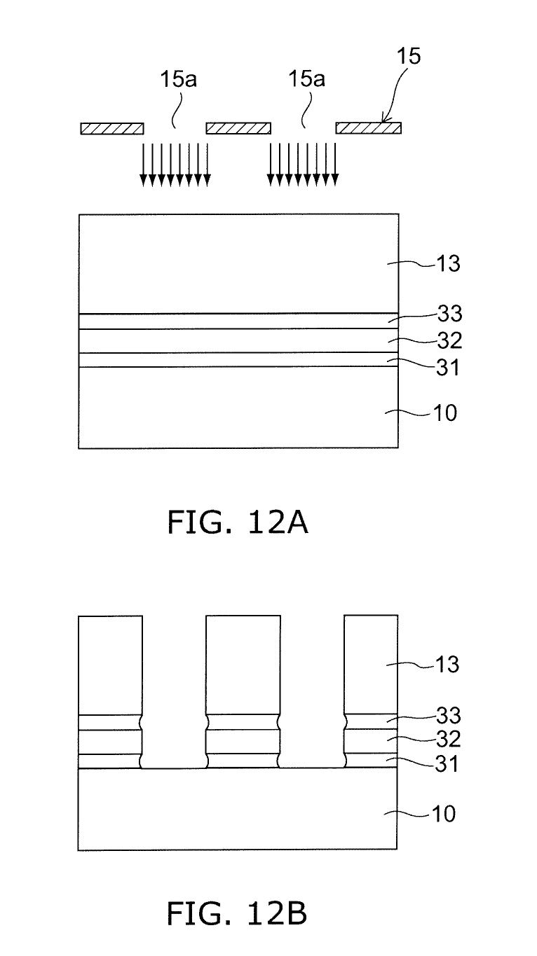

Next, FIGS. 11A to 12B show a semiconductor device manufacturing method according to a fifth embodiment of the invention.

In this embodiment, like the above fourth embodiment, a first anti-reflective coating 31 and a second anti-reflective coating 32 are sequentially formed on a semiconductor wafer 10. Then, again by the spin-coating method, as shown in FIG. 11A, a third anti-reflective coating 33 is formed on the second anti-reflective coating 32. After dropping and applying the third anti-reflective coating 33, baking treatment is performed to evaporate solvent and cure the third anti-reflective coating 33.

The third anti-reflective coating 33, as well as the first anti-reflective coating 31, contains substantially no photosensitizer (photoacid generator), and both the light-exposed portion and the non-light-exposed portion dissolve in the resist developer. In regard to the overall anti-reflective coating composed of the first to third anti-reflective coatings 31-33, the lower portion including a portion in contact with the semiconductor wafer 10 and the upper portion including a portion in contact with a resist film have a lower photoacid generator concentration than the intermediate portion between these portions.

Next, as shown in FIG. 11B, a resist film 13 is formed to a thickness of e.g. 200 nm on the third anti-reflective coating 33. This resist film 13 is a chemically amplified positive resist in which the light-exposed portion generates acid and becomes soluble in the developer.

Next, as shown in FIG. 12A, using a reticle 15 in which light transmitting portions 15a are selectively formed in accordance with a desired circuit pattern, the resist film 13 is selectively irradiated with light. After this light exposure, as shown in FIG. 12B, the resist film 13 is selectively removed and patterned by development illustratively using an alkaline developer. That is, a portion of the resist film 13 where acid is generated by irradiation with exposure light becomes soluble in the developer and is removed.

The first anti-reflective coating 31 and the third anti-reflective coating 33 are non-photosensitive, and both the light-exposed portion and the non-light-exposed portion are dissolved in the developer. On the other hand, in the second anti-reflective coating 32, only the light-exposed portion is soluble in the aforementioned developer, and is removed.

After the aforementioned development, the pattern of the resist film 13 is used as a mask to perform various processes, such as ion implantation, wet processing, and dry etching, on the semiconductor wafer 10.

Also in this embodiment, because the first anti-reflective coating 31 and the second anti-reflective coating 32 are formed, a similar effect to that of the above fourth embodiment is obtained.

Furthermore, in this embodiment, the third anti-reflective coating 33 formed in direct contact with the resist film 13 is non-photosensitive and has little interaction with the resist film 13. This prevents shape degradation of the resist film 13 after development. Hence, the resist film 13 is not substantially restricted in its type. On the other hand, the second anti-reflective coating 32 is photosensitive. Hence, if the resist film 13 is directly formed thereon, it is difficult to achieve compatibility with the resist film 13, which is also photosensitive. However, in this embodiment, the second anti-reflective coating 32 is not in direct contact with the resist film 13. Hence, there is no interaction therebetween, and the types of the second anti-reflective coating 32 and the resist film 13 can be freely selected without consideration for compatibility with each other.

Because the first anti-reflective coating 31 and the third anti-reflective coating 33 are non-photosensitive, corrosion from the lateral side occurs also in the non-light-exposed portion. Hence, the function of supporting the resist film 13 by being left therebelow is preferably served by the second anti-reflective coating 32, whose non-light-exposed portion is insoluble in the developer. Thus, the second anti-reflective coating 32 is preferably made thicker than the first anti-reflective coating 31 and the third anti-reflective coating 33. For instance, in this embodiment, the thickness of the first anti-reflective coating 31 and the third anti-reflective coating 33 is approximately 10 nm each, and the thickness of the second anti-reflective coating 32 is approximately several tens nm (such as 20 nm).

Furthermore, in the second anti-reflective coating 32, which is photosensitive, by suitably setting the photosensitizer concentration therein, the light-exposed portion can be removed throughout the thickness even in a relatively short etching time. Reduced etching time serves to limit the amount of corrosion on the lateral side of the first anti-reflective coating 31 and the third anti-reflective coating 33.

### Sixth Embodiment

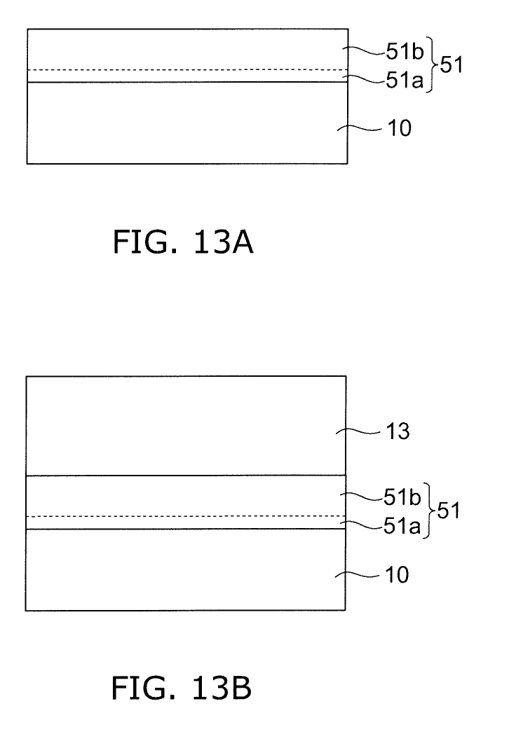

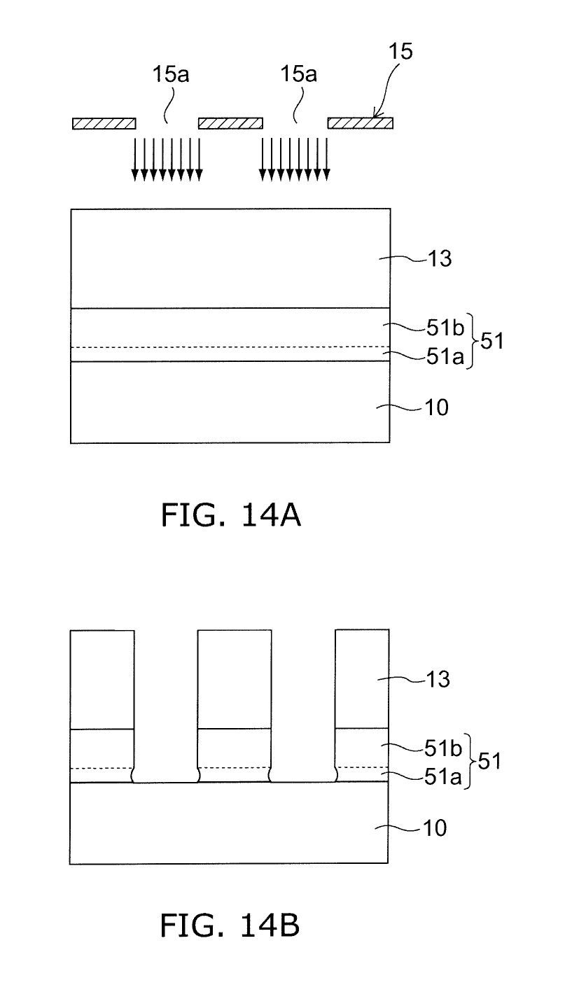

Next, FIGS. 13A to 14B show a semiconductor device manufacturing method according to a sixth embodiment of the invention.

First, as shown in FIG. 13A, an anti-reflective coating 51 is formed on a semiconductor wafer 10. Specifically, the anti-reflective coating 51 is formed by the spin-coating method of dropping the anti-reflective coating 51 in liquid form on the semiconductor wafer 10 fixed on a rotary support by a vacuum chuck and spinning the semiconductor wafer 10. After dropping and applying the anti-reflective coating 51, baking treatment is performed to evaporate solvent and cure the anti-reflective coating 51. The thickness of the anti-reflective coating 51 is e.g. approximately 40 nm.

In this embodiment, when the anti-reflective coating 51 is formed on the semiconductor wafer 10, a concentration variation of the photosensitizer is produced along the film thickness. Specifically, a solution in which two types of polymers, photosensitive and non-photosensitive, are mixed is dropped on the semiconductor wafer 10, and a concentration variation of the photosensitive polymer and the non-photosensitive polymer is produced along the film thickness using, for instance, the interaction between the semiconductor wafer 10 and the polymers, the polymer surface energy, the interaction between the polymers, and hydrophobicity to the surface of the semiconductor wafer 10.

Specifically, the lower portion on the semiconductor wafer 10 side is caused to contain the non-photosensitive polymer in a relatively large proportion, and the upper portion is caused to contain the photosensitive polymer in a relatively large proportion. That is, in the anti-reflective coating 51, the lower portion 51a including a portion in contact with the semiconductor wafer 10 contains the non-photosensitive polymer in a relatively large proportion, whereas the upper portion 51b thereabove contains the photosensitive polymer in a relatively large proportion.

After the anti-reflective coating 51 is formed, as shown in FIG. 13B, a resist film 13 is formed to a thickness of e.g. 200 nm on the anti-reflective coating 51. This resist film 13 is a chemically amplified positive resist in which the light-exposed portion generates acid and becomes soluble in the developer.

Next, as shown in FIG. 14A, using a reticle 15 in which light transmitting portions 15a are selectively formed in accordance with a desired circuit pattern, the resist film 13 is selectively irradiated with exposure light. After this light exposure, as shown in FIG. 14B, the resist film 13 is selectively removed and patterned by development illustratively using an alkaline developer. That is, a portion of the resist film 13 where acid is generated by irradiation with exposure light becomes soluble in the developer and is removed.

The lower portion 51a of the anti-reflective coating 51 is substantially non-photosensitive, and both the light-exposed portion and the non-light-exposed portion are dissolved in the developer. On the other hand, in the upper portion 51b of the anti-reflective coating 51, only the light-exposed portion is dissolved in the aforementioned developer, and is removed.

After the aforementioned development, the pattern of the resist film 13 is used as a mask to perform various processes, such as ion implantation, wet processing, and dry etching, on the semiconductor wafer 10.

Like the above fourth and fifth embodiments, this embodiment is also suitable to processing a stepped portion of the surface of the semiconductor wafer 10. More specifically, the lower portion 51a, which is soluble in the developer even in the non-light-exposed portion, is formed on the lower side where exposure light is more likely to fail to reach. Hence, even if such a stepped portion as illustrated in FIGS. 15A and 15B is present on the surface of the semiconductor wafer 10 and prevents light from reaching deeply into the gap, the lower portion 51a can be dissolved in the developer and removed.

Hence, as long as exposure light reaches the upper portion 51b, the resist film 13 and the anti-reflective coating 51 in the light-exposed portion can be removed, and the surface of the semiconductor wafer 10 in that portion can be exposed. In this view, the thickness ratio between the lower portion 51a and the upper portion 51b is preferably set by selecting, for instance, components in the aforementioned liquid mixture, the component ratio thereof, and the condition during spin-coating so as to ensure that the upper portion 51b in the gap between the stepped portions is exposed to light throughout the thickness.

Furthermore, in the lower portion 51a where the non-light-exposed portion is also soluble in the developer, corrosion from the lateral side occurs also in a portion below the resist film 13. Hence, the function of supporting the resist film 13 by being left therebelow is preferably served by the upper portion 51b, whose non-light-exposed portion is insoluble in the developer. More specifically, the upper portion 51b, which is superior in shape controllability at the time of development, serves to stably support the resist film 13. Hence, components in the aforementioned liquid mixture, the component ratio thereof, and the condition during spin-coating, for instance, are preferably adjusted so that the upper portion 51b is thicker than the lower portion 51a.

Furthermore, in this embodiment, there is no need to perform forming the anti-reflective coating 51 multiple times, but the coating process can be completed at one time. This serves to prevent increase in the number of processes and reduce cost.

Furthermore, in the upper portion 51b, which is photosensitive, by suitably setting the photosensitizer concentration therein, the light-exposed portion can be removed throughout the thickness even in a relatively short etching time. Reduced etching time serves to limit the amount of corrosion on the lateral side of the lower portion 51a.

In this embodiment, a solution in which a photosensitive polymer and a non-photosensitive polymer are mixed is used as a material for the anti-reflective coating 51. However, a single photosensitive solution can be used as in the above second embodiment. By adjusting the molecular weight of the photosensitizer contained therein, the number of rotations of the semiconductor wafer during spin-coating, baking temperature, baking time, and the atmosphere pressure on the semiconductor wafer, for instance, the photosensitizer can be moved along the film thickness to produce a concentration variation of the photosensitizer along the thickness of the anti-reflective coating.

The embodiments of the invention have been described with reference to examples. However, the invention is not limited to thereto, but can be variously modified within the spirit of the invention.

In the above embodiments, the photosensitizer-containing anti-reflective coating and the resist film are illustratively of the positive type. However, the invention is also applicable to those of the negative type. Furthermore, the photosensitizer is not limited to those generating acid upon light exposure, but may be any photosensitizer as long as the light-exposed portion becomes soluble or insoluble in a developer in response to exposure light.

1. A semiconductor device manufacturing method comprising:
forming an anti-reflective coating on a semiconductor wafer, the anti-reflective coating having varied photosensitizer concentration along its thickness;
forming a resist film on the anti-reflective coating;
selectively exposing the resist film to light;
developing the resist film and the anti-reflective coating after the light exposure; and
processing the semiconductor wafer using as a mask a pattern of the resist film obtained by the development.

2. The method according to claim 1, wherein the anti-reflective coating has a heterogeneous multilayer structure.

3. The method according to claim 1, wherein the photosensitizer concentration in the anti-reflective coating is lower in a portion in contact with the semiconductor wafer than in a portion in contact with the resist film.

4. The method according to claim 3, wherein the forming the anti-reflective coating includes:
forming, on the semiconductor wafer, a first anti-reflective coating whose light-exposed portion and non-light-exposed portion are both soluble in a developer during the development; and
forming, on the first anti-reflective coating, a second anti-reflective coating whose light-exposed portion or non-light-exposed portion is soluble in the developer.

5. The method according to claim 4, wherein in the second anti-reflective coating, the light-exposed portion is soluble in the developer.

6. The method according to claim 4, wherein the second anti-reflective coating is thicker than the first anti-reflective coating.

7. The method according to claim 3, wherein
the forming the anti-reflective coating includes supplying onto the semiconductor wafer a solution in which a photosensitive polymer and a non-photosensitive polymer are mixed, and
the photosensitive polymer is contained in an upper portion of the anti-reflective coating in a relatively high proportion, and the non-photosensitive polymer is contained in a lower portion of the anti-reflective coating in a relatively high proportion.

8. The method according to claim 3, wherein in the forming the anti-reflective coating, a concentration gradient of the photosensitizer is produced along the thickness of the anti-reflective coating.

9. The method according to claim 1, wherein in the anti-reflective coating, the photosensitizer concentration is higher in a portion in contact with the semiconductor wafer than in a portion in contact with the resist film.

10. The method according to claim 9, wherein the forming the anti-reflective coating includes:
forming, on the semiconductor wafer, a first anti-reflective coating whose light-exposed portion or non-light-exposed portion is soluble in a developer during the development; and
forming, on the first anti-reflective coating, a second anti-reflective coating whose light-exposed portion and non-light-exposed portion are both soluble in the developer.

11. The method according to claim 10, wherein in the first anti-reflective coating, the light-exposed portion is soluble in the developer.

12. The method according to claim 10, wherein the first anti-reflective coating is thicker than the second anti-reflective coating.

13. The method according to claim 9, wherein in the forming the anti-reflective coating, a concentration gradient of the photosensitizer is produced along the thickness of the anti-reflective coating.

14. The method according to claim 9, wherein
the forming the anti-reflective coating includes supplying onto the semiconductor wafer a solution in which a photosensitive polymer and a non-photosensitive polymer are mixed, and
the photosensitive polymer is contained in a lower portion of the anti-reflective coating in a relatively high proportion, and the non-photosensitive polymer is contained in an upper portion of the anti-reflective coating in a relatively high proportion.

15. The method according to claim 1, wherein the photosensitizer concentration in the anti-reflective coating is lower in a portion in contact with the semiconductor wafer and a portion in contact with the resist film than in an intermediate portion between these portions.

16. The method according to claim 15, wherein the forming the anti-reflective coating includes:
forming, on the semiconductor wafer, a first anti-reflective coating whose light-exposed portion and non-light-exposed portion are both soluble in a developer during the development;
forming, on the first anti-reflective coating, a second anti-reflective coating whose light-exposed portion or non-light-exposed portion is soluble in the developer; and
forming, on the second anti-reflective coating, a third anti-reflective coating whose light-exposed portion and non-light-exposed portion are both soluble in a developer.

17. The method according to claim 16, wherein in the second anti-reflective coating, the light-exposed portion is soluble in the developer.

18. The method according to claim 16, wherein the second anti-reflective coating is thicker than the first anti-reflective coating and the third anti-reflective coating.

19. The method according to claim 1, wherein in the anti-reflective coating, a portion with the photosensitizer concentration being low has a smaller thickness than a portion with the photosensitizer concentration being high.

20. The method according to claim 1, wherein the photosensitizer is a photoacid generator that generates acid by an exposure light.
